(19) United States
(12) Patent Application Publication
(10) Pub. No.: US 2026/0173294 A1
(43) Pub. Date: Jun. 18, 2026

(54) Electronic Circuit Enclosure with Magnetic Attachment Device

(71) Applicant: Monte Neal, Covina, CA (US)

(72) Inventor: Monte Neal, Covina, CA (US)

(21) Appl. No.: 18/981,150

(22) Filed: Dec. 13, 2024

(51) Int. Cl. H05K 7/14; H05K 5/04

(52) U.S. Cl. CPC H05K 7/1417; H05K 5/04

(57) ABSTRACT

An electronics enclosure mounting assembly includes a rectangular steel enclosure, having a top, bottom, front, back, first side and second side. A hinged opening portion exposes an inside surface of the enclosure when open. The inside surface holds a plurality of electronics assemblies, each of which are magnetically mounted in the electronics enclosure and have magnetic attachment portions which connect to surfaces of the rectangular enclosure. The electronics assemblies on the magnetic standoffs can be moved to different locations in the enclosure and are held by magnetic force between the magnetic attachment portions and the steel surface of the enclosure.

### BACKGROUND OF THE INVENTION

Electronic circuit enclosures are typically formed as steel boxes known as enclosures that contain internal circuits, operational devices such as power supplies, and connection components, such as connectors and terminal blocks. The electronic circuit enclosures have openings that allow access to the inside of the boxes. These openings can be removable or hinged doors or panels.

When the electronic circuitry is inside the enclosure, that circuitry is shielded by the metal structure of the enclosure. The enclosure protects against shock hazard to people from the circuits being electrically energized, protects against fire, allows cooling of the circuitry, and protects against noise and interference.

Different enclosures are of different sizes and support different amounts of circuitry to be put inside the enclosure.

If the enclosure is modified by making holes in the enclosure, then the enclosure could lose its UL or NEMA rating, except where there are factory knock outs (“KO's”) for electrical conduit connections. Accordingly, enclosures are often purchased for the very specific purpose for which they are intended.

### SUMMARY

The inventor recognizes that it can be desirable to reconfigure the inside of an electronics enclosure without drilling holes, for example to add additional or alternative components.

Also, over time, different generations of components can change in size and shape. However, it may be desirable to use those newly sized components in an existing electronics enclosure. For example, it may be desirable to use updated power supplies, switches, wiring types and other items in the existing electronics enclosure.

In some situations, an enclosure needs to be of a certain size, but over time the circuit boards and other components that go in the enclosure may change in size. This produces a challenging situation, making it difficult to put the proper amount of circuitry inside the proper enclosure.

An embodiment describes a magnetic attachment system for electronic circuitry in an electronic enclosure.

One embodiment describes forming a magnetic standoff devices that holds the electronics in the system in a desired location. Because the standoff devices are magnetic, the circuits can be moved to different locations inside the enclosure and are not limited to the fixed location where the circuit attachment parts are located.

Another embodiment describes a metal attachment plane, which can be attached to a part of the enclosure, for example: on a hinged door of the enclosure and enables an additional location for attaching circuitry.

### BRIEF DESCRIPTION OF THE DRAWINGS

The drawings show aspects of the invention, specifically:

FIG. 1 shows an electronics enclosure with relocatable circuits therein; and

FIG. 2 shows a closeup of a board with magnetic location parts.

### DETAILED DESCRIPTION

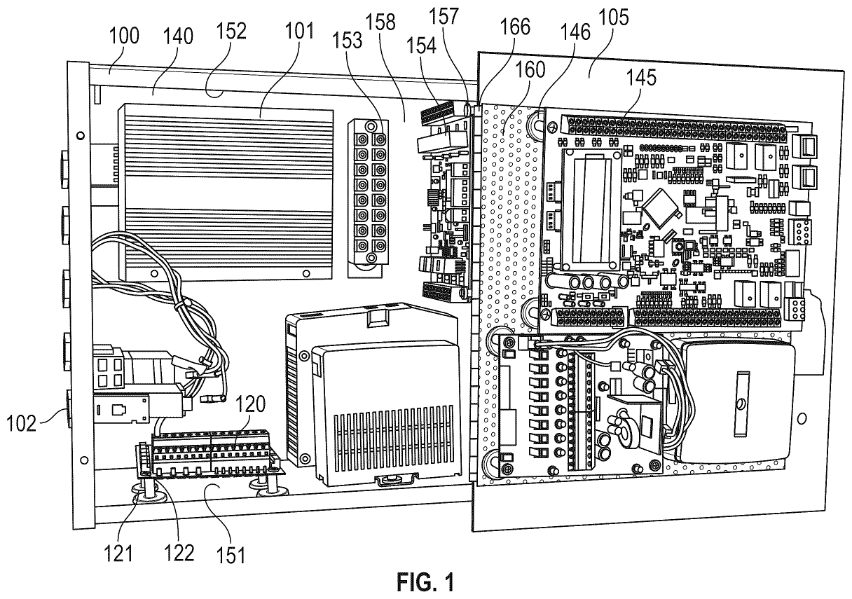

An embodiment is shown in FIG. 1. An enclosure 100 for electronics is shown with its door in the open position. The enclosure includes an enclosure cavity 101 inside of the enclosure, with a number of connector openings 102. This inside of the enclosure is accessible by a hinged door 105 which is hinged on hinges 106. The door can be opened to allow access to the enclosure cavity 101 that holds the different operative circuit components and closed to operate.

The enclosure cavity 101 includes a number of different assemblies therein. Each of a plurality of the assemblies are mounted on standoffs that terminate on magnetic bases. The magnetic bases are attached to different metal surfaces on the inside surface of the enclosure cavity 101 and can be easily moved to any desired location inside the enclosure cavity. Because the assemblies can be freely moved in the enclosure cavity, the assemblies can be more efficiently located to any location inside the enclosure cavity and without making any holes in any surface of the enclosure.

A first assembly 120 is a terminal block assembly which is formed of a terminal block circuit 200, having standoffs 201, 202, 203 mounted at each of its four sides. Each standoff is formed by a screw 205 which screws through an insulating sleeve 210, into a magnetic base 215. The magnetic base 215 can be for example between ½ and 1½ inches.

The magnetic base preferably has magnets that are strong enough to hold the assembly in place on the circuit board. This allows the assembly 120 to be placed on any metal surface on the inside of the enclosure.

Other assemblies are also similarly mounted on standoffs and can be placed at any location inside the enclosure. There are also standoffs on the other circuitry, including on the switch 140, and the circuit boards 145. The circuit board 145 is similarly configured with standoff assemblies 146, which have magnetic bottoms and enable the circuit to be placed anywhere where there is a magnetic surface.

In this embodiment, an additional circuit mounting surface 160 is attached to the open surface of the door. The additional circuit mounting surface 160 is a perforated magnetic metal sheet that is mounted to the door surface 105. In one embodiment the perforated metal sheet is mounted on standoffs to space the metal sheet from the door surface.

The entire surface of the additional mounting surface 160 has perforations thereon, thus forming a perforated surface spaced from but parallel to the inside of the open surface of the door. In one embodiment, the perforations are ⅛-inch openings, that are spaced every ¼ inch. This allows an additional surface mounting on the door. Also, the perforations can carry out multiple specific functions. First, they allow airflow which can assist in cooling. The perforations reduce the weight of the mounting surface, allowing for better mounting on the door of the enclosure. Secondly the perforations have less than perfect flatness near the holes, and this less than perfect flatness can increase friction to prevent sliding by the different circuitry that is attached on magnetic standoffs.

As shown in FIG. 1, a number of circuit board assemblies such as 145 can be located on the door. Wires attaching to the circuits need to be long enough to allow the door to open and have enough extra space to allow the doors to similarly close.

This flexible configuration allows the circuits to be magnetically attached to any and all of the bottom surface 151 of the enclosure, the top surface 152 of the enclosure, the front surface 153 of the enclosure, the rear surface 154 of the enclosure, the side surface of the enclosure, and the door of the enclosure. This turns each of these surfaces into attachment surfaces for the electronic circuitry.

In an embodiment, electronic circuits are attached on magnetic standoffs to all of the bottom surface 151 of the enclosure, the top surface 152 of the enclosure, the front surface 153 of the enclosure, the rear surface 154 of the enclosure, the side surface of the enclosure, and the door of the enclosure.

FIG. 1 illustrates the terminal block assembly 120 located to the bottom surface 151 of the enclosure. A power supply 140 is mounted to the top surface of the enclosure 152. The side surface of the enclosure 153 includes a terminal block 154 mounted thereon. The rear surface of the enclosure 157 includes a terminal block 154. Also, the door 105 includes the plane 160 that includes electronic circuits such as 146 thereon.

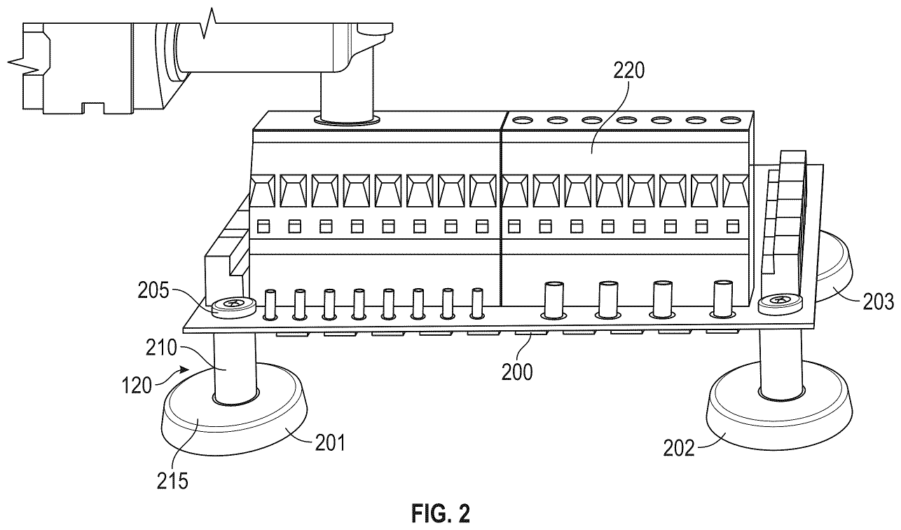

FIG. 2 shows a close-up of the terminal assembly, although the other assemblies can be mounted in similar ways. The circuit board 200 in FIG. 2 has holes at each of the four corners, such as at 205. A screw 205 is placed through the hole, which extends through a standoff 210 and is held by the magnetic feet. The magnetic feet and standoff assembly are located at each of the four corners, 201, 202, 203, but also at the other corner that cannot be seen in FIG. 2.

In the embodiment, all of the circuit boards in the enclosure are mounted on standoffs and are mounted on the stand metal surfaces of the enclosure.

Although only a few embodiments have been disclosed in detail above, other embodiments are possible, and the inventors intend these to be encompassed within this specification. The specification describes certain technological solutions to solve the technical problems that are described expressly and inherently in this application. This disclosure describes embodiments, and the claims are intended to cover any modification or alternative or generalization of these embodiments which might be predictable to a person having ordinary skill in the art.

The embodiments described herein can be used to enclose any electronics circuitry and are not limited to the embodiments described herein.

Also, the inventor(s) intend that only those claims which use the words “means for” are intended to be interpreted under 35 USC 112, sixth paragraph. Moreover, no limitations from the specification are intended to be read into any claims, unless those limitations are expressly included in the claims.

The previous description of the disclosed exemplary embodiments is provided to enable any person skilled in the art to make or use the present invention. Various modifications to these exemplary embodiments will be readily apparent to those skilled in the art, and the generic principles defined herein may be applied to other embodiments without departing from the spirit or scope of the invention. Thus, the present invention is not intended to be limited to the embodiments shown herein but is to be accorded the widest scope consistent with the principles and novel features disclosed herein.

For example, this can be applied to other electronics besides the ones described herein. Other kinds of sensors and detectors can be used.

What is claimed is:

1. An electronics enclosure mounting assembly comprising:
a rectangular enclosure, having a top, bottom, front, back, first side and second side;
the rectangular enclosure having an opening portion on the second side, where the opening portion on the second side hinges to open, and when open, exposes an inside surface of the enclosure on the second side;
a plurality of electronics assemblies, mounted in the electronics enclosure, each of the electronics assemblies being magnetically mounted in the electronics enclosure and having magnetic attachment portions which connect to surfaces of the rectangular enclosure.

2. The enclosure assembly as in claim 1, wherein each of the electronics assemblies includes multiple standoffs, attached to the electronics assembly at one end, and attached to a magnetic attachment part at the other end, and the magnetic attachment part being attached to the surfaces of the rectangular enclosure.

3. The enclosure assembly as in claim 2, wherein the rectangular enclosure has electronics assemblies on all of the top surface, bottom surface, front surface, back surface, first side, and inside surface of the second side.

4. The enclosure assembly as in claim 1, wherein the inside surface of the second side includes an additional mounting surface attached thereto.

5. The enclosure assembly as in claim 4, wherein the additional mounting surface is a corrugated steel plate with holes in the plate.

6. The enclosure assembly as in claim 5, further comprising multiple electronics circuits attached to the additional mounting surface.
